(19) United States
(12) Patent Application Publication
(10) Pub. No.: US 2026/0212907 A1
(43) Pub. Date: Jul. 23, 2026

(54) 3D Compatible 2 Transistor-N Capacitor Ferroelectric Random Access Memory it Quasi-Nondestructive Readout Characteristics

(71) Applicants: The Penn State Research Foundation, University Park, PA (US); University of Notre Dame du Lac, South Bend, IN (US)

(72) Inventors: Yi Xiao, University Park, PA (US); Shan Deng, Notre Dame, IN (US); Vijaykrishnan Narayanan, University Park, PA (US); Kai Ni, Notre Dame, IN (US)

(73) Assignees: The Penn State Research Foundation, University Park, PA (US); University of Notre Dame du Lac, South Bend, IN (US)

(21) Appl. No.: 19/566,137

(22) Filed: Mar. 13, 2026

Related U.S. Application Data
(63) Continuation of application No. 18/680,191, filed on May 31, 2024.

(51) Int. Cl. G11C 11/22

(52) U.S. Cl. CPC G11C 11/2273; G11C 11/221; G11C 11/2275

(57) ABSTRACT

Embodiments can relate to techniques for sensing capacitor polarization in a random access memory (RAM) cell by: applying a read gate bias to a transistor; allowing or causing ferroelectric polarization (P_{FE}) of a capacitor to set a threshold voltage (V_{TH}); and performing a read operation by sensing polarization in a capacitor. Performing the read operation can occur in a quasi-nondestructive manner due to the structure of the RAM cell, which can include: plural capacitors connected to node 1, each individual capacitor also connected to an individual write bit line (WBL); a write transistor (T_{W}) connected to: node 1, a write word line (WWL), and a write plate line (WPL); and a read transistor (T_{R}) connected to: node 1, a read bit line (RBL), and a read source line (RSL). The RAM cell allows for performing plural read operations without a write-back operation to restore polarization in a capacitor.

### STATEMENT REGARDING FEDERALLY SPONSORED RESEARCH AND DEVELOPMENT

This invention was made with government support under Grant No. DE-SC0021118 awarded by the Department of Energy and under Grant No. 2239284 awarded by the National Science Foundation. The Government has certain rights in the invention.

### FIELD OF THE INVENTION

Embodiments can relate to techniques for sensing capacitor polarization in a random access memory (RAM) cell. An exemplary technique can involve applying a read gate bias to a transistor of the RAM cell, allowing or causing ferroelectric polarization (P_{FE}) of a capacitor to set a threshold voltage (V_{TH}) for the RAM cell, and performing a read operation by sensing polarization in a capacitor of the RAM cell.

### BACKGROUND OF THE INVENTION

Ferroelectric capacitor memory devices exhibit excellent write performance, such as low operating voltage and high reliability. However, to sense the stored ferroelectric polarization (P_{FE}) of a capacitor of the memory, it is necessary to switch the polarization and then measure the resulting switching current. This results in destruction of an established state for the memory (e.g., a destructive sensing process), thereby requiring a write-back operation to restore P_{FE} after every read operation. Consequently, conventional ferroelectric memory devices must operate to endure more than 10¹⁵ write cycles.

### SUMMARY OF THE INVENTION

An exemplary embodiment can relate to a random access memory (RAM) cell. The RAM cell can include plural capacitors connected to node 1, each individual capacitor connected to an individual write bit line (WBL). The RAM cell can include a write transistor (T_{W}) connected to: node 1, a write word line (WWL), and a write plate line (WPL). The RAM cell can include a read transistor (T_{R}) connected to: node 1, a read bit line (RBL), and a read source line (RSL).

In some embodiments, the RAM cell can be a 2 Transistor-n Capacitor (2TnC) cell.

In some embodiments, the RAM cell can include one or more voltage sources connected to each WBL, the WWL, the WPL and/or the RSL.

In some embodiments, the one or more voltage sources can be configured to generate one or more voltage pulses.

In some embodiments, one or more capacitors can be a metal-ferroelectric-metal (MFM) capacitor.

In some embodiments, the T_{W} and/or the T_{R} can be a field-effect-transistor (FET).

An exemplary embodiment can relate to a method for sensing capacitor polarization in a random access memory (RAM) cell. The method can involve applying a read gate bias to a transistor of the RAM cell. The method can involve allowing or causing ferroelectric polarization (P_{FE}) of a capacitor to set a threshold voltage (V_{TH}) for the RAM cell. The method can involve performing a read operation by sensing polarization in a capacitor of the RAM cell.

In some embodiments, performing the read operation can occur in a quasi-nondestructive manner.

In some embodiments, the RAM cell can include: plural capacitors connected to node 1, each individual capacitor connected to an individual write bit line (WBL); a write transistor (T_{W}) connected to node 1, connected to a write word line (WWL), and connected to a write plate line (WPL); and a read transistor (T_{R}) connected to node 1, connect to a read bit line (RBL), and connected to a read source line (RSL). The method can involve performing the read operation involves turning OFF the T_{W}, applying a read voltage (V_{R}) to the WBL, and sensing T_{R} current.

In some embodiments, the method can involve performing plural read operations without a write-back operation to restore polarization in the capacitor.

In some embodiments, the method can involve generating separate read and write paths by: performing a write operation to turn ON T_{W}; generating a first operating state for the RAM cell by applying: one or more voltage pulses (VWBL) to one or more capacitors; and one or more voltage pules (VWPL) to the T_{W}; and/or generating a second operating state for the RAM cell by applying: one or more voltage pulses (VWBL) to one or more capacitors; and one or more voltage pules to the T_{W}.

In some embodiments, the method can involve performing plural read operations before accumulative P _{FE} switching leads to destruction of the first state or the second state.

In some embodiments, the RAM cell can be a 2 Transistor-n Capacitor (2TnC) cell.

In some embodiments, one or more capacitors can be a metal-ferroelectric-metal (MFM) capacitor.

In some embodiments, the T_{W} and/or the T_{R} can be a field-effect-transistor (FET).

Further features, aspects, objects, advantages, and possible applications of the present invention will become apparent from a study of the exemplary embodiments and examples described below, in combination with the Figures, and the appended claims.

### BRIEF DESCRIPTION OF THE DRAWINGS

The above and other objects, aspects, features, advantages and possible applications of the present innovation will be more apparent from the following more particular description thereof, presented in conjunction with the following drawings. Like reference numbers used in the drawings may identify like components.

FIG. 1 (panel a) shows a conventional FeRAM’s destructive read requiring high endurance, FIG. 1 (panel b) shows a conventional FeFET suffering from poor write performance and reliability, and FIG. 1 (panel c) shows an exemplary embodiment of a 2TnC FeRAM realizing QNRO with good write performance.

FIG. 2A shows the establishment of separate paths for read and write in an exemplary embodiment of the memory cell, and FIG. 2B shows how conventional memory cells merely establish the same read and write paths.

FIG. 3A shows a QFE-V FE and FIG. 3B shows a dQFE/dV FE hysteresis loop. FIG. 3C shows ID-VG of T_{R} and FIG. 3D shows a waveform illustrating correct sensing of ‘0’ and ‘1’. FIG. 3E shows that read cycle can reach 107. FIG. 3F shows ION, IOFF rises with increasing V_{R}. The curves in (e) and (f) are for visual guidance and not fitting curves.

FIGS. 4A, 4B, 4C, and 4D show a design space of 2TnC cell for QNRO against two design parameters, A_{MFM}/A_{TR} and V_{TH},_{TR}, wherein FIG. 4A I_{ON}/I_{OFF}, FIG. 4B ∆Q₀, and FIG. 4C I_{ON} are presented. FIG. 4D shows that target design parameters are obtained.

FIG. 5A shows waveforms that verifies 2T8C FeRAM’s functionality, and FIG. 5B shows ΔQ0 and I_{ON}/I_{OF}F for 16, 32, and 64 MFM capacitors.

FIG. 6A shows that the 2TnC structure can be integrated in 3D. FIG. 6B shows one potential CIM application of 2TnC cell can be TCAM.

### DETAILED DESCRIPTION OF THE INVENTION

The following description is of exemplary embodiments that are presently contemplated for carrying out the present invention. This description is not to be taken in a limiting sense, but is made merely for the purpose of describing the general principles and features of the present invention. The scope of the present invention is not limited by this description.

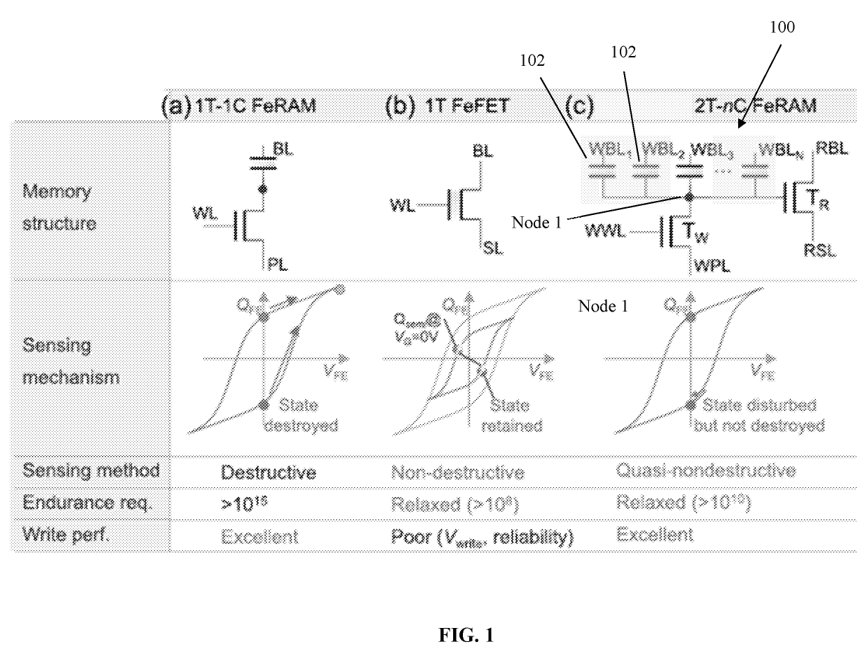

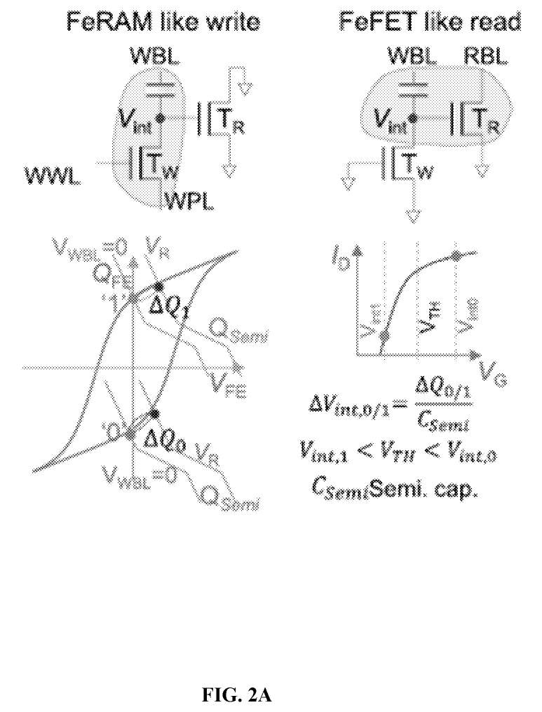

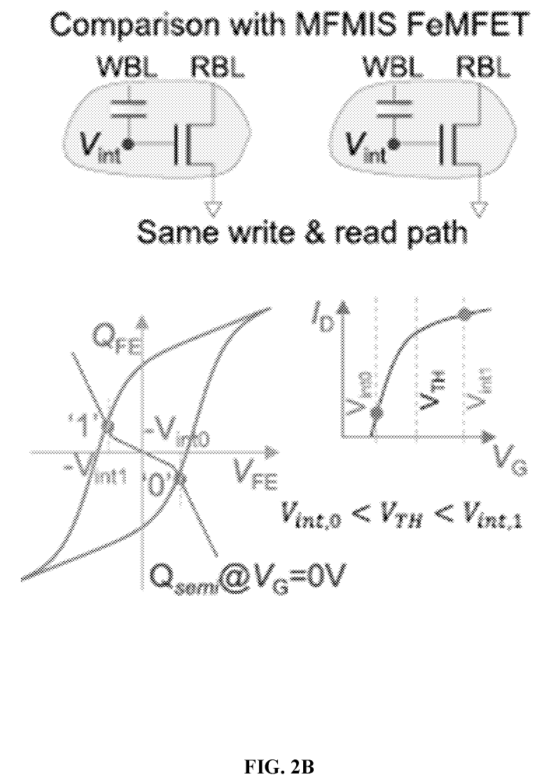

Referring to FIGS. 1-2, an exemplary embodiment can relate to a random access memory (RAM) cell 100. It is contemplated for the RAM cell 100 to be a 2 Transistor-n Capacitor (2TnC) RAM cell 100.

An exemplary RAM cell 100 can include plural capacitors 102. One or more capacitors 102 of the RAM cell 100 can be a metal-ferroelectric-metal (MFM) capacitor 102. While one or more of the capacitors 102 can be connected to node 1, it is contemplated for each capacitor 102 of the plural capacitors 102 to be connected to node 1. While one or more capacitors 102 can be connected to one or more write bit line (WBL), it is contemplated for each individual capacitor 102 to be connected to an individual WBL. The RAM cell 100 can include one or more write transistors (T_{W}). It is contemplated for the RAM cell 100 to include a single T_{W}. The T_{W} can be connected to node 1. While the T_{W} can be connected to one or more write word lines (WWL), it is contemplated for the T_{W} to be connected to a single WWL. While the T_{W} can be connected to one or more write plate lines (WPL), it is contemplated for the T_{W} to be connected to a single WPL. The RAM cell 100 can include one or more read transistors (T_{R}). It is contemplated for the RAM cell 100 to include a single T_{R}. The T_{R} can be connected to node 1. While the T_{R} can be connected to one or more read bit lines (RBL), it is contemplated for the T_{R} to be connected to a single read bit line (RBL). While the T_{R} can be connected to one or more read source lines (RSL), it is contemplated for the T_{R} to be connected to a single read source line (RSL).

T_{W} and/or the T_{R} can be a field-effect-transistor (FET).

The RAM cell 100 may include one or more voltage sources (e.g., battery, potential difference generator, etc.) connected to each WBL, the WWL, the WPL and/or the RSL. The voltage source(s) can be configured to generate one or more voltage pulses.

An exemplary embodiment can relate to a method for sensing capacitor polarization in an embodiment of the RAM cell 100. The method can involve applying a read gate bias to a transistor (e.g., T_{R}) of the RAM cell 100, thereafter allowing or causing ferroelectric polarization (P_{FE}) of a capacitor 102 to set a threshold voltage (V_{TH}) for the RAM cell 100. A read operation can then be performed by sensing polarization in a capacitor 102 of the RAM cell 100. The read operation can involve turning OFF the T_{W}, applying a read voltage (V_{R}) to the WBL, and sensing T_{R} current. The structure of the RAM cell 100 facilitates performing the read operation in a quasi-nondestructive manner. This allows for performing plural read operations without a write-back operation to restore polarization in the capacitor(s) 102.

More specifically, and referring to FIGS. 2A and 2B, the structure RAM cell 100 facilitates generating separate read and write paths. For instance, T_{W} is turned ON during a write operation, whereby a first operating state for the RAM cell 100 can be generated or established by applying: one or more voltage pulses (VWBL) to one or more capacitors 102; and one or more voltage pulses (VWPL) to the T_{W}. A second operating state for the RAM cell 100 can be generated or established by applying: one or more voltage pulses (VWBL) to one or more capacitors 102; and one or more voltage pulses (VWPL) to the T_{W}. Plural read operations can be performed before accumulative P _{FE} switching leads to destruction of the first state or the second state.

### EXAMPLES

The following examples include exemplary implementations and test results of embodiments disclosed herein.

The following examples demonstrate a 2TnC ferroelectric random access memory (FeRAM) cell design to realize the quasi-nondestructive readout (QNRO) of ferroelectric polarization (P_{FE}) in a capacitor, which can relax the endurance requirement of the ferroelectric thin film and exploit the benefits of both conventional 1T1C FeRAM and ferroelectric FET (FeFET). We demonstrate that: i) QNRO sensing of P_{FE} can be conducted successfully in experiment with a ON/OFF ratio (I_{ON}/I_{OFF}) > 10³, I_{ON} > 10 µA, and read endurance >10⁶ cycles, which can relax the metal-ferroelectric-metal (MFM) capacitor endurance requirement by 10⁶x; ii) optimization of the cell performance can be realized by tuning the metal-ferroelectric-metal capacitor (MFM) capacitor to read transistor area ratio and read transistor threshold voltage (V_{TH}); iii) the 2TnC cell structure is 3D-compatible, enabling integration of highly dense memory solution; and iv) the 2TnC cell structure also enables compute-in-memory (CIM) applications of FeRAM, which has not been widely explored. With this technology, storage and memory-centric computing can be enabled.

FIG. 1 (panel a) shows a conventional 1T1C FeRAM’s destructive read requiring high endurance, FIG. 1 (panel b) shows a conventional FeFET suffering from poor write performance and reliability, and FIG. 1 (panel c) shows an exemplary embodiment of a 2TnC FeRAM realizing QNRO with good write performance.

As indicated above, ferroelectric HfO₂ has revived interests in high performance and low power ferroelectric memory devices, including capacitor based 1T1C FeRAM and transistor based FeFET. The HfO₂ based FeRAM with 1 transistor and 1 MFM capacitor structure, as shown in FIG. 1 (panel a) is promising for its excellent write performance, such as low operating voltage and high reliability. However, to sense the stored P_{FE} of a MFM capacitor, it is necessary to switch the polarization and then measure the resulting switching current. The destructive sensing process thus demands a write-back operation to restore P_{FE} after every read operation. Therefore, it is crucial that 1T1C FeRAM should ideally endure more than 10¹⁵ write cycles, which is a nontrivial engineering effort and yet achieved.

In contrast, the ferroelectric polarization can be sensed out non-destructively in a FeFET as the P_{FE} sets the device threshold voltage (V_{TH}), which can be easily read out through the channel current. Applying a small read gate bias, the read disturb to P_{FE} is negligible allowing almost infinite read cycles, thus relaxing the write endurance requirements for FeFET to around 10⁸ cycles. However, FeFET suffers from its high write voltage and poor reliability mainly associated with the large charge mismatch between the ferroelectric layer and the semiconductor. To avoid the challenges of both devices while exploiting their advantages, an exemplary 2TnC FeRAM cell is explored, which can support multiple read cycles before the need of writing back, hence called quasi-nondestructive readout (QNRO).

FIG. 2A shows QNRO of a 2TnC FeRAM, which relies on the difference of ∆Q₀ and ∆Q₁ in a MFM capacitor. FIG. 2B shows that compared to FeMFET, the exemplary 2TnC FeRAM has a lower V_{Write}, higher retention time, and higher memory density due to T_{W}/T_{R} sharing. The exemplary 2TnC cell shown in FIG. 1 (panel c) consists of a write transistor (T_{W}), a read transistor (T_{R}) and multiple MFM capacitors. During the write process, T_{W} is turned ON and the selected MFM’s P_{FE} is set to different states by applying V_{WBL} (write bit line) and VWPL (write plate line) pulses, as shown in FIG. 2A. The write process of the exemplary 2TnC FeRAM is similar to the conventional 1T1C FeRAM, therefore the same write performance is expected. The idea of QNRO of FeRAM, however, is to switch small but enough polarization to turn ON a read transistor channel such that multiple read cycles can be supported before a write- back is needed. The read is conducted by turning OFF the T_{W}, applying a V_{R} to the WBL, and then sensing T_{R} current. If the P_{FE} is positive (e.g., point to channel, bit ‘1’), a positive V_{R} will cause almost zero P_{FE} switching (e.g., ∆Q₁ or the effective capacitance of the state ‘1’ is small). As a result, the internal voltage (Vᵢₙₜ) sees a small change, thereby leading to a small T_{R} current. On the other hand, if P_{FE} is negative (e.g., point to gate), more P_{FE} switching is induced (e.g., ∆Q₀ is large enough), albeit still significantly lower than conventional 1T1C FeRAM sensing. As a result, Vᵢₙₜ will be high, leading to a large T_{R} current. By utilizing this approach, P_{FE} can be read multiple cycles before accumulative P_{FE} switching leads to the destruction of the state ‘0’.

It is worth noting that there is a significant difference between the exemplary 2TnC FeRAM structure and the conventional ferroelectric- metal FET (FeMFET). FeMFET utilizes the same path for both writing and reading process and stores information on the Vᵢₙₜ, modulated by P_{FE}, as shown in FIG. 2B. However, this approach may be prone to retention loss induced by leakage. In comparison, the exemplary 2TnC FeRAM leverages two separate write and read paths, exploiting 1T1C FeRAM’s excellent write performance and approximating FeFET’s non-destructive read operation. In addition, it is important to distinguish the exemplary 2TnC design from other conventional 2T1C designs. In previous designs, the sensing of P_{FE}, though done through the T_{R}, is still conducted through full polarization switching, similar to conventional 1T1C FeRAM, thus not addressing the excessive endurance requirement. Combining the QNRO of P_{FE} and the 2TnC structure is a unique contribution of the exemplary 2TnC design. The exemplary 2TnC structure also provides the advantage of sharing the (T_{W}) and (T_{R}) among multiple MFM capacitors, thereby enhancing the integration density.

Experimental demonstration of QNRO.

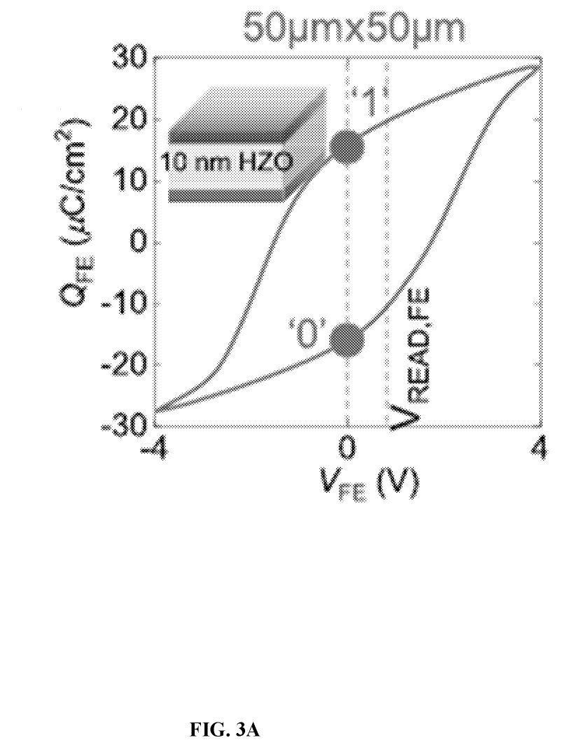

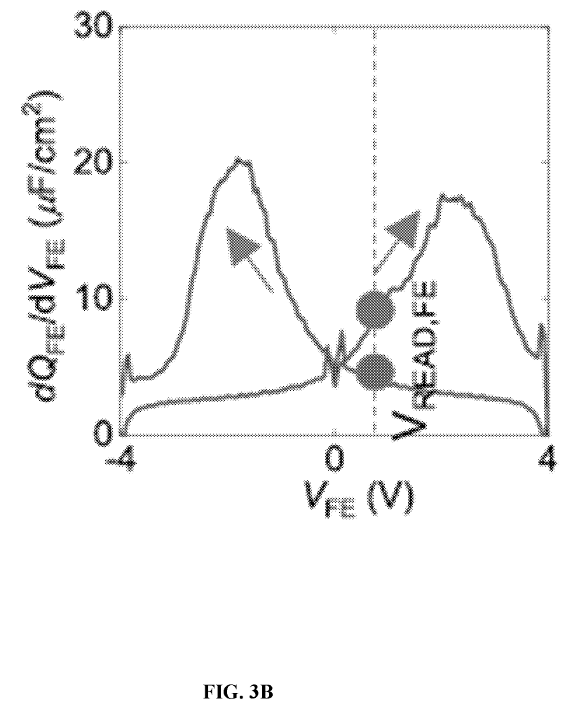

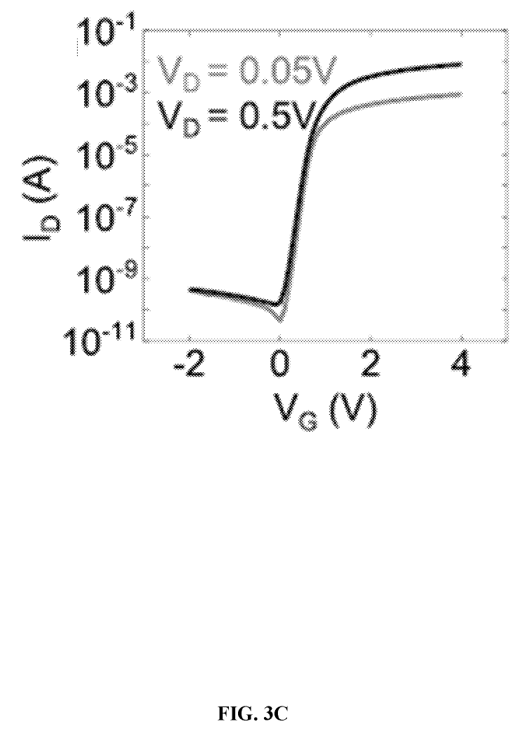

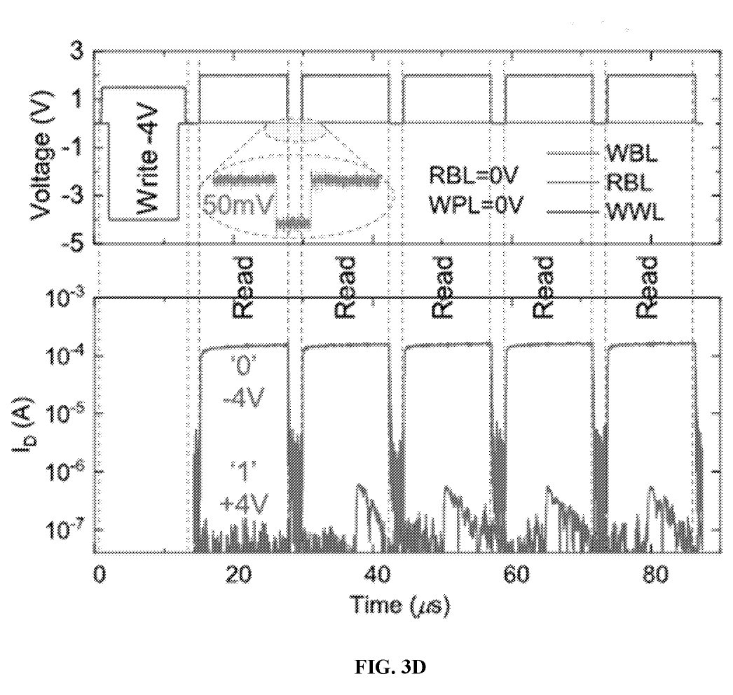

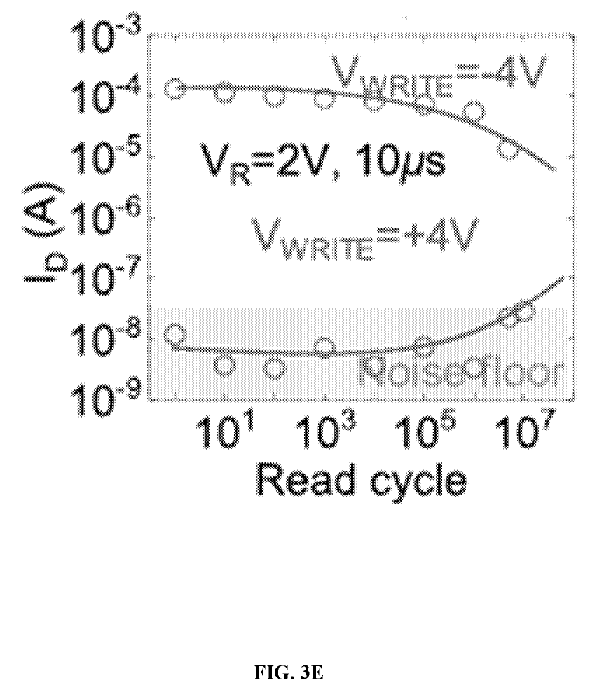

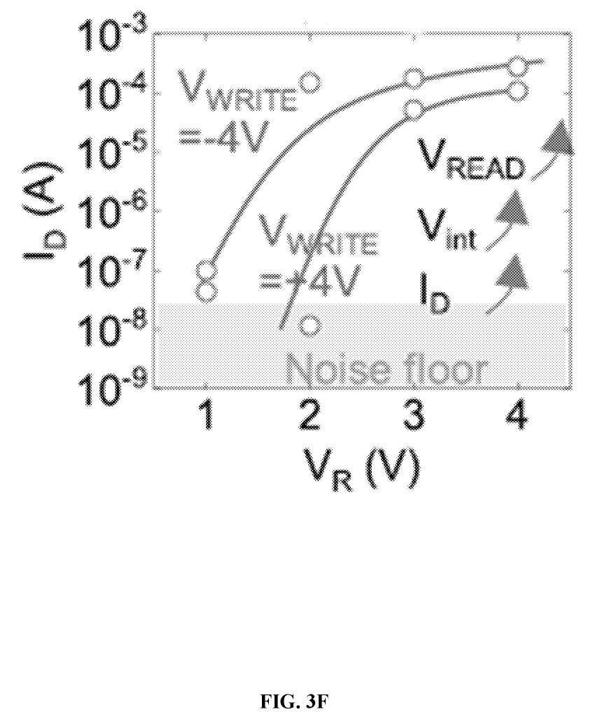

FIG. 3A shows a Q_{FE}-V_{FE} and FIG. 3B shows a dQ_{FE}/dV_{FE} hysteresis loop. FIG. 3C shows I_{D}-V_{G} of T_{R} and FIG. 3D shows a waveform illustrating correct sensing of ‘0’ and ‘1’. FIG. 3E shows that read cycle can reach 107. FIG. 3F shows I_{ON}, I_{OFF} rises with increasing V_{R}. The curves in (e) and (f) are for visual guidance and not fitting curves.

The QNRO operation is verified using a 2T1C cell built discretely with a 10nm thick Hf_{0.5}Zr_{0.5}O₂ MFM capacitor and two discrete transistors (e.g., ALD1103). The fabrication process of Hf_{0.5}Zr_{0.5}O₂ MFM capacitor is shown in. The hysteresis loop of Q_{FE}-V_{FE} (FIG. 3A) and the dynamic capacitance obtained by taking the derivative of Q_{FE} with respect to V_{FE} (FIG. 3B) reveal the difference in capacitance between state ‘0’ and ‘1’, which is the origin of QNRO operation. FIG. 3C shows the T_{R} I_{D}-V_{G} curves. The MFM capacitance is about 3 larger than the T_{R} gate capacitance. FIG. 3D illustrates a transient waveform that corresponds to the writing of the MFM capacitor, which is then followed by five cycles of QNRO sensing. The operational principle remains the same as depicted in FIG. 2A, where the W_{WL} provides a voltage of 1.5V to activate T_{W}, and a voltage of 4/-4V is applied to W_{BL} to write a bit ‘1’ or ‘0’.

Shortly after programming, the T_{W} is switched OFF, and V_{R} is applied to W_{BL}. FIG. 3C shows that the state ‘0’ (i.e., written with -4V) has a higher current than state ‘1’ (e.g., written with 4V), opposite to FeMFET. FIG. 3D shows the evolution of sensed current over multiple read cycles, indicating that the read endurance of the device is greater than 10⁶ cycles with no significant degradation in sensing margin. This indicates that the endurance requirement for HfO₂ 2TnC FeRAM can be relaxed by >10⁶ times, making HfO₂ 2TnC FeRAM more practical for various applications. Additionally, an optimal V_{R} exists, as shown in FIG. 3E and FIG. 3F, to achieve the maximum I_{ON}/I_{OFF} as a too low V_{R} shuts OFF the T_{R}; while a too high V_{R} turns ON T_{R}, irrespectively of the P_{FE}.

Design space exploration of 2TnC cell.

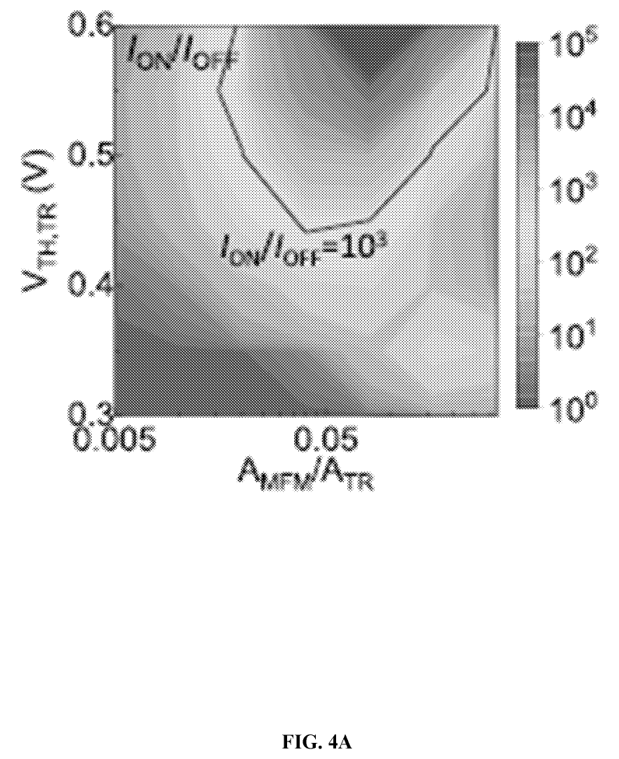

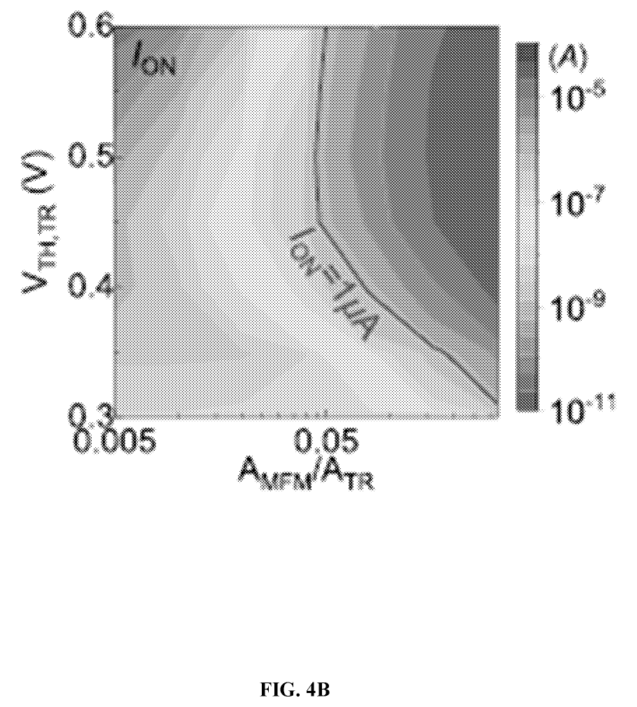

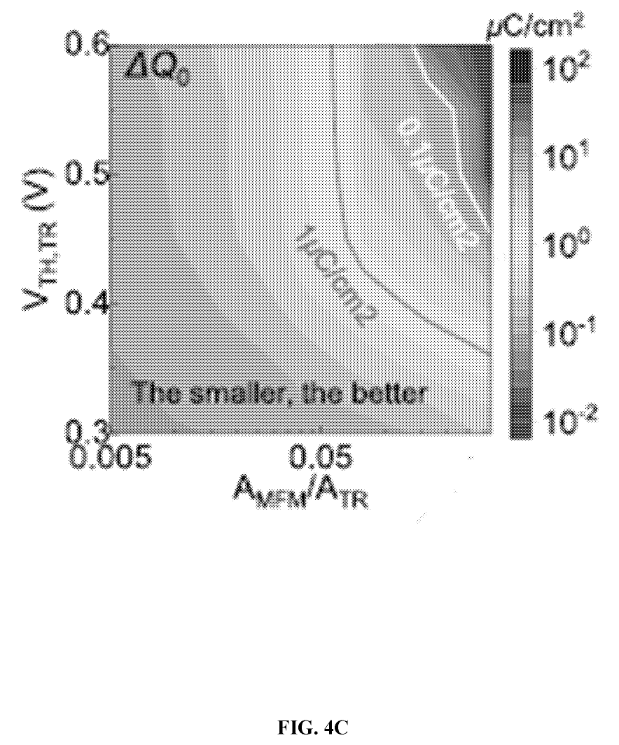

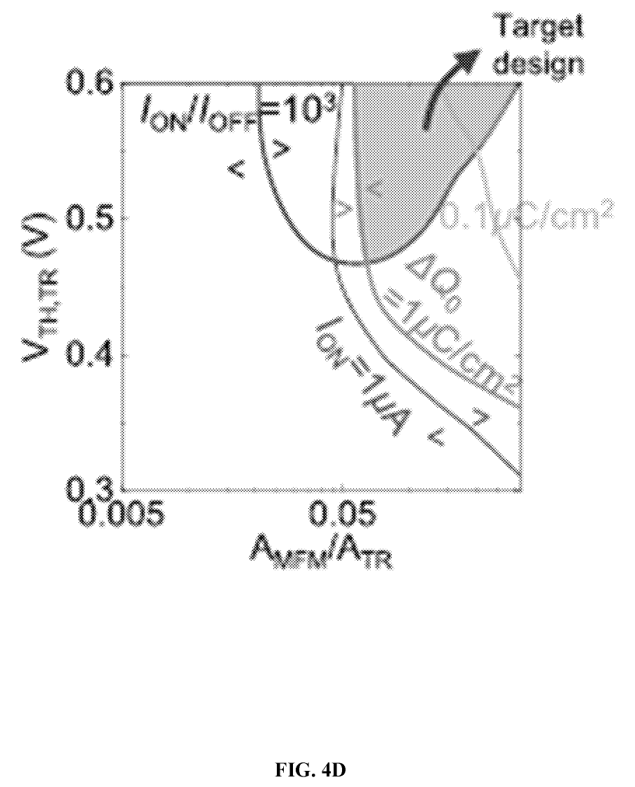

FIGS. 4A, 4B, 4C, and 4D show a design space of 2TnC cell for QNRO against two design parameters, A_{MFM}/A_{TR} and V_{TH}, _{TR}, wherein FIG. 4A I_{ON}/I_{OFF}, FIG. 4B ∆Q₀, and FIG. 4C I_{ON} are presented. FIG. 4D shows that target design parameters are obtained.

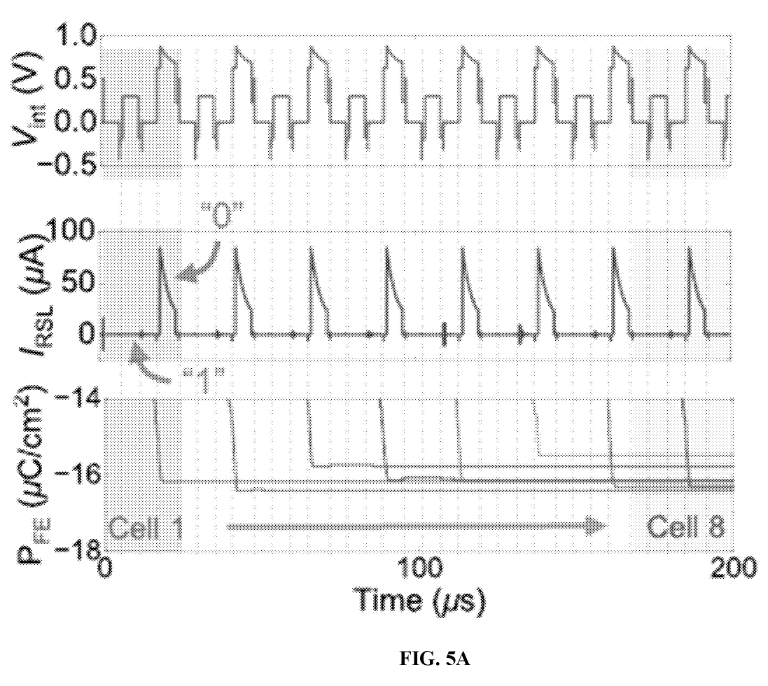

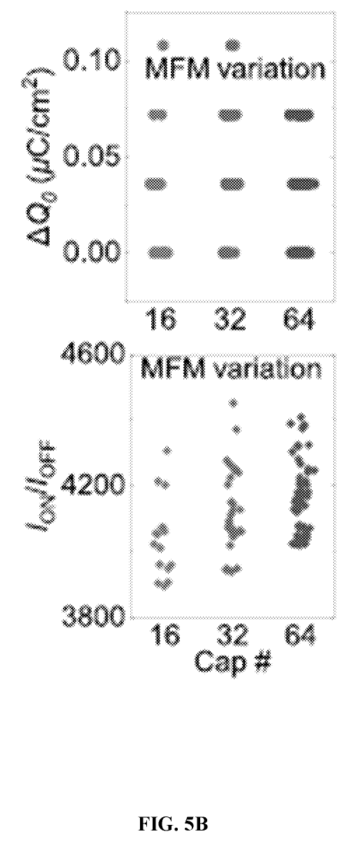

To investigate the design space for an exemplary 2TnC cell, a hybrid SPICE model is built. T_{W} and T_{R} are simulated using 45nm PTM model and the capacitor(s) is/are modeled with a calibrated Monte Carlo model capturing the domain distribution and switching stochasticity. Two parameters (e.g., area ratio of MFM capacitor to the T_{R} (A_{MFM}/A_{TR}) and V_{TH} of T_{R} (V_{TH,TR})) are studied with the goal of high I_{ON}, large ON/OFF ratio, and small polarization change when sensing state ‘0’ (i.e., ∆Q₀). Without loss of generality, the area of the T_{R} (A_{TR}) is kept at 2 µm², while the A_{MFM} is adjusted to tune the voltage division between the MFM and T_{R} during read operation. FIGS. 4A-D shows the design space of the 2T1C cell in terms of I_{ON}/I_{OFF} ratio (FIG. 4A), I_{ON} (FIG. 4B), and ∆Q₀ (FIG. 4C)) for fixed write ( 2V, 5µs) and read pulse (1.2V, 5µs). Since only one capacitor is read at a time while the others are floating, 2T1C, being equivalent to 2TnC, is studied here for the readout while 2TnC operation is studied in FIGS. 5A-B. Note that the slow speed is because the MFM model is calibrated with switching dynamics of a large MFM capacitor with significant parasitics and by no means the intrinsic operation limit as sub-ns switching has been demonstrated. As the A increases, its capacitance also increases, resulting in a higher Vᵢₙₜ and lower V_{FE}. This phenomenon accounts for the observed increase in I_{ON}, shown in FIG. 4B, and decrease in ∆Q₀, shown in FIG. 4C, with an increase in the A_{MFM}/A_{TR} ratio. The I_{ON}/I_{OFF} ratio, which is extracted at a V_{TH,TR} of 0.5V, displays a peak at a given A_{MFM}. This is because a small A_{MFM}/A_{TR} results in a low Vᵢₙₜ even for ON state while a large A_{MFM}/A_{TR} causes a high Vᵢₙₜ even for the OFF state. Both cases reduce the I_{ON}/I_{OFF} ratio. The V_{TH,TR} is another parameter that affects voltage division between MFM and the T_{R}, thus modulating Vᵢₙₜ by ensuring charge conservation between the two. When considering different values of V_{TH,TR}, it was observed that while both the I_{ON} and ∆Q₀ tend to saturate after 0.5 V due to the simultaneous increase of Vᵢₙₜ and V_{TH,TR}, the I_{ON}/I_{OFF} ratio continues to increase within a reasonable range of V_{TH,TR}.

FIG. 5A shows waveforms that verifies 2T8C FeRAM’s functionality, and FIG. 5B shows ΔQ₀ and I_{ON}/I_{OFF} for 16, 32, and 64 MFM capacitors.

The target design parameters, which are illustrated in FIG. 4D, were obtained to achieve an I_{ON}/I_{OFF}>10³, ∆Q₀<1µC/cm² for QNRO, and I_{ON}>1µA simultaneously. Note that modeling results aim at unraveling the mechanisms of the device and do not necessarily match the experimental results as the devices differ significantly. In case engineering V_{TH,TR} is not practical, the read operation can be augmented with a pre-charge phase, where Vᵢₙₜ can be set to an initial value, equivalent to V_{TH,TR} engineering. The simulation results are omitted here due to space limit. FIG. 5A shows the transient waveform of writing and reading a 2T8C FeRAM cell. It shows successful memory operation and the small P_{FE} change during read, thus demonstrating its QNRO characteristics. The simulation results of 16, 32 and 64 MFM capacitors per 2TnC FeRAM cell, shown in FIG. 5B, also indicate that a large I_{ON}/I_{OFF} can be obtained with QNRO with a high integration density. The simulated device variation is based on different sampling of the domain distribution function and only accounts for intrinsic variation sources. In an 2TnC FeRAM array, T_{W} and T_{R} are shared across multiple cells. When writing, half-selected MFM capacitors in the same row or column of the target cell get V_{w}/2, while unselected capacitors remain undisturbed. Disturb-free reading is achieved by selecting the target WBL and floating other WBLs, allowing column-wise operation.

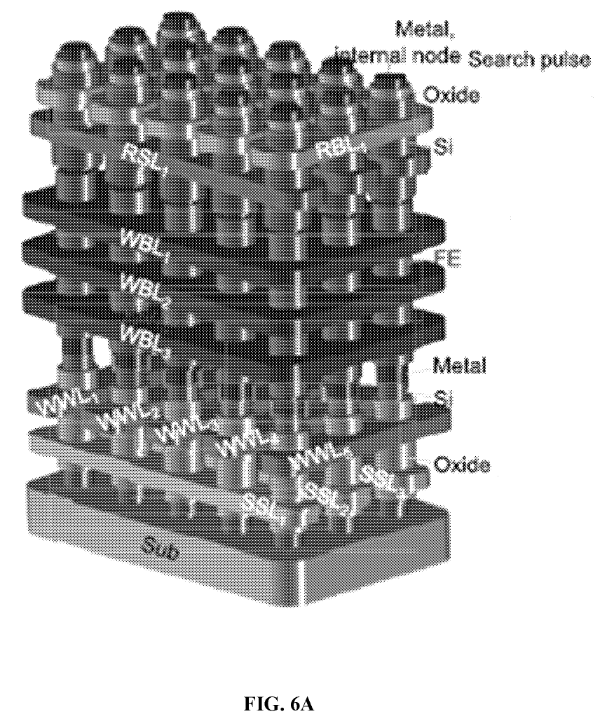

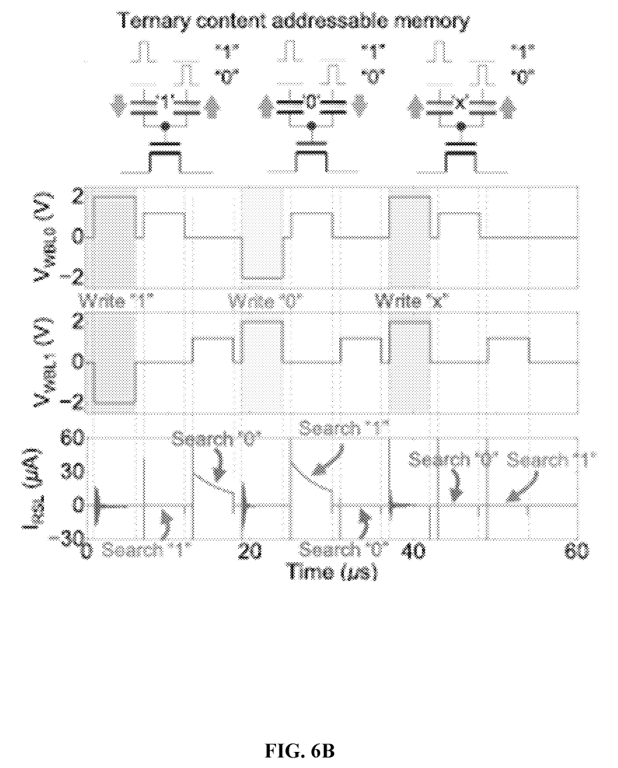

FIG. 6A shows that the 2TnC FeRAM structure can be integrated in 3D. FIG. 6B shows one potential CIM application of 2TnC FeRAM cell can be TCAM. By encoding write and read pulses, TCAM operation is validated.

It should be noted that the 2TnC FeRAM cell is compatible with dense 3D integration, as shown in FIG. 6A. Each string corresponds to a 2TnC FeRAM cell. By hiding the T_{R} and T_{W} footprint in the vertical 3D structure, the memory density can be enhanced. This compatibility allows for the potential of enabling dense memory. In addition, the QNRO scheme allows FeRAM to be utilized in compute-in-memory (CIM) applications, which has long been limited by the destructive read operation in conventional FeRAM technology. The CIM implementation has the same design requirements as the memory as long as only a single MFM capacitor in the 2TnC FeRAM cell is active at a time. For instance, by using two MFM capacitors, a ternary content addressable memory (TCAM) can be constructed, as shown in FIG. 6B. For the state 0 and 1 storage, the information is stored as complementary P_{FE} states in the two capacitors, while for the state X storage, both capacitors are programmed to positive P_{FE}. Then, the search information is encoded as which capacitor receives the read pulse. In this way, the successful TCAM operation was verified, which allows to detect whether the stored information matches the search query. Compared to other FeFET-based TCAM implementations, e.g., 2FeFET , 2FeFET-1T & 2FeFET-2T , the disclosed design reduces write voltage and improves reliability.

As can be appreciated from the present disclosure, the inventors have exploited and validated a 2TnC FeRAM cell to sense a capacitor polarization in a quasi-nondestructive manner, which can allow multiple read cycles before a write-back operation is needed. This working principle can push the HfO₂ based FeRAM into a technology by relaxing the endurance requirement to a practical level. A comprehensive design space exploration is conducted for the better design of the cell. A potential 3D structure and a compute-in-memory example are demonstrated. This QNRO memory therefore paves the way for wider application of FeRAM technology.

References.

The references listed below are incorporated herein by reference in their entireties.

1 U. Schroeder, M. H. Park, T. Mikolajick, and C. S. Hwang, “The fundamentals and applications of ferroelectric HfO2,” Nature Rev. Mater., vol. 7, no. 8, pp. 653–669, Mar. 2022, doi: 10.1038/s41578022 004312.

2 H. Mulaosmanovic, E. T. Breyer, S. Dunkel, S. Beyer, T. Mikolajick, and S. Slesazeck, “Ferroelectric field-effect transistors based on HfO2: A review,” Nanotechnology, vol. 32, no. 50, Dec. 2021, Art. no. 502002, doi: 10.1088/13616528/ac189f.

3 A. I. Khan, A. Keshavarzi, and S. Datta, “The future of ferroelectric field-effect transistor technology,” Nature Electron., vol. 3, no. 10, pp. 588–597, Oct. 2020, doi: 10.1038/s41928020 004927.

4 J. Okuno, T. Kunihiro, K. Konishi, H. Maemura, Y. Shuto, F. Sugaya, M. Materano, T. Ali, K. Kuehnel, K. Seidel, U. Schroeder, T. Mikolajick, M. Tsukamoto, and T. Umebayashi, “SoC compatible 1T1C FeRAM memory array based on ferroelectric Hf0.5Zr0.5O2,” in Proc. IEEE Symp. VLSI Technol., Jun. 2020, pp. 1–2, doi: 10.1109/VLSITechnology18217.2020.9265063.

5 R. Zambrano, “Challenges for integration of embedded FeRAMs in the sub-180 nm regime,” Integr. Ferroelectr., vol. 53, no. 1, pp. 247–255, Mar. 2003, doi: 10.1080/10584580390258165.

6 J. Muller, P. Polakowski, S. Mueller, and T. Mikolajick, “Ferroelectric hafnium oxide based materials and devices: Assessment of current status and future prospects,” ECS J. Solid State Sci. Technol., vol. 4, no. 5, pp. 30–35, 2015, doi: 10.1149/2.0081505jss.

7 T. Francois, L. Grenouillet, J. Coignus, P. Blaise, C. Carabasse, N. Vaxelaire, T. Magis, F. Aussenac, V. Loup, C. Pellissier, S. Slesazeck, V. Havel, C. Richter, A. Makosiej, B. Giraud, E. T. Breyer, M. Materano, P. Chiquet, M. Bocquet, E. Nowak, U. Schroeder, and F. Gaillard, “Demonstration of BEOL-compatible ferroelectric Hf0.5Zr0.5O2 scaled FeRAM co-integrated with 130 nm CMOS for embedded NVM applications,” in IEDM Tech. Dig., Dec. 2019, p. 15, doi: 10.1109/IEDM19573.2019.8993485.

8 J. Okuno, T. Kunihiro, K. Konishi, H. Maemura, Y. Shuto, F. Sugaya, M. Materano, T. Ali, M. Lederer, K. Kuehnel, K. Seidel, U. Schroeder, T. Mikolajick, M. Tsukamoto, and T. Umebayashi, “High-endurance and low-voltage operation of 1T1C FeRAM arrays for nonvolatile memory application,” in Proc. IEEE Int. Memory Workshop (IMW), May 2021, pp. 1–3, doi: 10.1109/IMW51353.2021.9439595.

9 S. Deng, Z. Zhao, S. Kurinec, K. Ni, Y. Xiao, T. Yu, and V. Narayanan, “Overview of ferroelectric memory devices and reliability aware design optimization,” in Proc. Great Lakes Symp. VLSI, Jun. 2021, pp. 473–478, doi: 10.1145/3453688.3461743.

10 S. Slesazeck, U. Schroeder, and T. Mikolajick, “Embedding hafnium oxide based FeFETs in the memory landscape,” in Proc. Int. Conf. IC Design Technol. (ICICDT), Jun. 2018, pp. 121–124, doi: 10.1109/ICICDT.2018.8399771.

11 S.-M. Yoon and H. Ishiwara, “Memory operations of 1T2C-type ferro- electric memory cell with excellent data retention characteristics,” IEEE Trans. Electron Devices, vol. 48, no. 9, pp. 2002–2008, Sep. 2001, doi: 10.1109/16.944189.

12 Y. Kato, T. Yamada, and Y. Shimada, “0.18 µm nondestructive readout FeRAM using charge compensation technique,” IEEE Trans. Electron Devices, vol. 52, no. 12, pp. 2616–2621, 2005, doi: 10.1109/TED.2005.859688.

13 S. Horita and B. N. Q. Trinh, “Nondestructive readout of ferroelectric gate field-effect transistor memory with an intermediate electrode by using an improved operation method,” IEEE Trans. Electron Devices, vol. 55, no. 11, pp. 3200–3207, Nov. 2008, doi: 10.1109/TED.2008.2003329.

14 K. Ni, J. A. Smith, B. Grisafe, T. Rakshit, B. Obradovic, J. A. Kittl, M. Rodder, and S. Datta, “SoC logic compatible multi-bit FeMFET weight cell for neuromorphic applications,” in IEDM Tech. Dig., Dec. 2018, p. 13, doi: 10.1109/IEDM.2018.8614496.

15 S. Yoon, D. Min, S. Moon, K. S. Park, J. I. Won, and S. Yoon, “Improvement in long-term and high-temperature retention stability of ferroelectric field-effect memory transistors with metal-ferroelectric-metal-insulator-semiconductor gate-stacks using al-doped HfO2 thin films,” IEEE Trans. Electron Devices, vol. 67, no. 2, pp. 499–504, Feb. 2020, doi: 10.1109/TED.2019. 2961117.

16 C. Sun, Z. Zheng, K. Han, S. Samanta, J. Zhou, Q. Kong, J. Zhang, H. Xu, A. Kumar, C. Wang, and X. Gong, “Temperature-dependent operation of InGaZnO ferroelectric thin-film transistors with a metal-ferroelectric-metal-insulator-semiconductor structure,” IEEE Electron Device Lett., vol. 42, no. 12, pp. 1786–1789, Dec. 2021, doi: 10.1109/LED.2021.3121677.

17 K. Ashikaga and T. Ito, “Analysis of memory retention characteristics of ferroelectric field effect transistors using a simple metal-ferroelectric- metal–insulator-semiconductor structure,” J. Appl. Phys., vol. 85, no. 10, pp. 7471–7476, May 1999, doi: 10.1063/1.369381.

18 S. Slesazeck, T. Ravsher, V. Havel, E. T. Breyer, H. Mulaosmanovic, and T. Mikolajick, “A 2TnC ferroelectric memory gain cell suitable for compute-in-memory and neuromorphic application,” in IEDM Tech. Dig., Dec. 2019, p. 38, doi: 10.1109/IEDM19573.2019.8993663.

19 E. Hsieh, J. Chang, T. Tang, Y. Li, C. Liang, M. Lin, S. Huang, C. Su, J. Guo, and S. Chung, “NVDimm-FE: A high-density 3D architecture of 3-bit/c 2TnC FE to break great memory wall with 10 ns of PGM-pulse, 1010 cycles of endurance, and decade lifetime at 103 ◦C,” in Proc. IEEE Symp. VLSI Technol. Circuits (VLSI Technol. Circuits), Jun. 2022, pp. 359–360, doi: 10.1109/VLSITechnologyand Cir46769.2022.9830515.

20 Y. Luo, J. Hur, Z. Wang, W. Shim, A. I. Khan, and S. Yu, “A technology path for scaling embedded FeRAM to 28 nm and beyond with 2T1C structure,” IEEE Trans. Electron Devices, vol. 69, no. 1, pp. 109–114, Jan. 2022, doi: 10.1109/TED.2021.3131108.

21 S. Deng, M. Benkhelifa, S. Thomann, Z. Faris, Z. Zhao, T.-J. Huang, Y. Xu, V. Narayanan, K. Ni, and H. Amrouch, “Compact ferroelectric programmable majority gate for compute- in-memory applications,” in IEDM Tech. Dig., 2022, pp. 7–36, doi: 10.1109/IEDM45625.2022.10019400.

22 S. Sinha, G. Yeric, V. Chandra, B. Cline, and Y. Cao, “Exploring sub-20 nm FinFET design with predictive technology models,” in Proc. DAC Design Autom. Conf., Jun. 2012, pp. 283–288, doi: 10.1145/2228360.2228414.

23 S. Deng, G. Yin, W. Chakraborty, S. Dutta, S. Datta, X. Li, and K. Ni, “A comprehensive model for ferroelectric FET capturing the key behav- iors: Scalability, variation, stochasticity, and accumulation,” in Proc. IEEE Symp. VLSI Technol., Jun. 2020, pp. 1–2, doi: 10.1109/VLSITechnology18217.2020.9265014.

24 X. Lyu, M. Si, P. R. Shrestha, K. P. Cheung, and P. D. Ye, “First direct measurement of sub-nanosecond polarization switching in ferroelectric hafnium zirconium oxide,” in IEDM Tech. Dig., Dec. 2019, p. 15, doi: 10.1109/IEDM19573.2019.8993509.

25 M. M. Dahan, H. Mulaosmanovic, O. Levit, S. Dunkel, S. Beyer, and E. Yalon, “Sub-nanosecond switching of Si:HfO2 ferroelectric field- effect transistor,” Nano Lett., vol. 23, no. 4, pp. 1395–1400, Feb. 2023, doi: 10.1021/acs.nanolett.2c04706.

26 K. Seidel, D. Lehninger, R. Hoffmann, T. Ali, M. Lederer, R. Revello, K. Mertens, K. Biedermann, Y. Shen, D. Wang, and M. Landwehr, “Memory array demonstration of fully integrated 1T-1C FeFET concept with separated ferroelectric MFM device in interconnect layer,” in Proc. IEEE Symp. VLSI Technol. Circuits (VLSI Technol. Circuits), Jun. 2022, pp. 355–356, doi: 10.1109/VLSITechnologyand Cir46769.2022.9830141.

27 D. Lehninger, R. Hoffmann, A. Sunbul, H. Mähne, T. Kämpfe, K. Bernert, S. Thiem, and K. Seidel, “Ferroelectric FETs with separated capacitor in the back-end-of-line: Role of the capacitance ratio,” IEEE Electron Device Lett., vol. 43, no. 11, pp. 1866–1869, Nov. 2022, doi: 10.1109/LED.2022.3204360.

28 T. Ravsher, H. Mulaosmanovic, E. T. Breyer, V. Havel, T. Mikolajick, and S. Slesazeck, “Adoption of 2T2C ferroelectric memory cells for logic operation,” in Proc. 26th IEEE Int. Conf. Electron., Circuits Syst. (ICECS), Nov. 2019, pp. 791–794, doi: 10.1109/ICECS46596.2019.8965155.

29 X. Yin, K. Ni, D. Reis, S. Datta, M. Niemier, and X. S. Hu, “An ultra- dense 2FeFET TCAM design based on a multi-domain FeFET model,” IEEE Trans. Circuits Syst. II, Exp. Briefs, vol. 66, no. 9, pp. 1577–1581, Sep. 2019, doi: 10.1109/TCSII.2018.2889225.

30 X. Yin, Y. Qian, M. Imani, K. Ni, C. Li, G. L. Zhang, B. Li, U. Schlichtmann, and C. Zhuo, “Ferroelectric ternary content addressable memories for energy-efficient associative search,” IEEE Trans. Comput. Aided Design Integr. Circuits Syst., vol. 42, no. 4, pp. 1099–1112, Apr. 2023, doi: 10.1109/TCAD.2022.3197694.

It should be understood that the disclosure of a range of values is a disclosure of every numerical value within that range, including the end points. It should also be appreciated that some components, features, and/or configurations may be described in connection with only one particular embodiment, but these same components, features, and/or configurations can be applied or used with many other embodiments and should be considered applicable to the other embodiments, unless stated otherwise or unless such a component, feature, and/or configuration is technically impossible to use with the other embodiment. Thus, the components, features, and/or configurations of the various embodiments can be combined together in any manner and such combinations are expressly contemplated and disclosed by this statement.

It will be apparent to those skilled in the art that numerous modifications and variations of the described examples and embodiments are possible considering the above teachings of the disclosure. The disclosed examples and embodiments are presented for purposes of illustration only. Other alternate embodiments may include some or all of the features disclosed herein. Therefore, it is the intent to cover all such modifications and alternate embodiments as may come within the true scope of this invention, which is to be given the full breadth thereof.

It should be understood that modifications to the embodiments disclosed herein can be made to meet a particular set of design criteria. Therefore, while certain exemplary embodiments of the systems, compositions, materials, apparatuses, and methods of using and making the same disclosed herein have been discussed and illustrated, it is to be distinctly understood that the invention is not limited thereto but may be otherwise variously embodied and practiced within the scope of the following claims.

What is claimed is:

1. A random access memory (RAM) cell, comprising:
plural capacitors connected to node 1, each individual capacitor connected to an individual write bit line (WBL);
a write transistor (T_{W}) connected to: node 1, a write word line (WWL), and a write plate line (WPL); and
a read transistor (T_{R}) connected to: node 1, a read bit line (RBL), and a read source line (RSL).

2. The RAM cell of claim 1, wherein:
the RAM cell is a 2 Transistor-n Capacitor (2TnC) cell.

3. The RAM cell of claim 1, further comprising:
one or more voltage sources connected to each WBL, the WWL, the WPL, the RBL and/or the RSL.

4. The RAM cell of claim 3, wherein:
the one or more voltage sources is configured to generate one or more voltage pulses.

5. The RAM cell of claim 1, wherein:
one or more capacitors is a metal-ferroelectric-metal (MFM) capacitor.

6. The RAM cell of claim 1, wherein:
the T_{W} and/or the T_{R} is a field-effect-transistor (FET).

7. A method for sensing capacitor polarization in a random access memory (RAM) cell, the method comprising:
applying a read gate bias to a transistor of the RAM cell;
allowing or causing ferroelectric polarization (P_{FE}) of a capacitor to set a threshold voltage (V_{TH}) for the RAM cell;
performing a read operation by sensing polarization in a capacitor of the RAM cell.

8. The method of claim 7, wherein:
performing the read operation occurs in a quasi-nondestructive manner.

9. The method of claim 7, wherein the RAM cell includes: plural capacitors connected to node 1, each individual capacitor connected to an individual write bit line (WBL); a write transistor (T_{W}) connected to node 1, connected to a write word line (WWL), and connected to a write plate line (WPL); and a read transistor (T_{R}) connected to node 1, connect to a read bit line (RBL), and connected to a read source line (RSL), wherein:
performing the read operation involves turning OFF the T_{W} applying a read voltage (V_{R}) to the W_{BL} and sensing T_{R} current.

10. The method of claim 7, further comprising:
performing plural read operations without a write-back operation to restore polarization in the capacitor.

11. The method of claim 9, further comprising:
generating separate read and write paths by:
performing a write operation to turn ON T_{W};
generating a first operating state for the RAM cell by applying: one or more voltage pulses (VWBL) to one or more capacitors; and one or more voltage pulses (VWPL) to the T_{W}; and/or
generating a second operating state for the RAM cell by applying: one or more voltage pulses (VWBL) to one or more capacitors; and one or more voltage pulses (VWPL) to the T_{W}.

12. The method of claim 11, further comprising:
performing plural read operations before accumulative P_{FE} switching leads to destruction of the first state or the second state.

13. The method of claim 7, wherein:
the RAM cell is a 2 Transistor-n Capacitor (2TnC) cell.

14. The method of claim 9, wherein:
one or more capacitors is a metal-ferroelectric-metal (MFM) capacitor.

15. The method of claim 9, wherein:
the T_{W} and/or the T_{R} is a field-effect-transistor (FET).
